(19) United States
(12) Patent Application Publication
(10) Pub. No.: US 2026/0206521 A1
(43) Pub. Date: Jul. 16, 2026

(54) SUBSTRATE PROCESSING METHOD, PROCESSED SUBSTRATE MANUFACTURING METHOD, AND CHIP MANUFACTURING METHOD

(71) Applicant: DISCO CORPORATION, Tokyo (JP)

(72) Inventor: Yoshinobu SAITO, Tokyo (JP)

(21) Appl. No.: 19/441,058

(22) Filed: Jan. 6, 2026

(30) Foreign Application Priority Data
Jan. 14, 2025 (JP) 2025-004632

(51) Int. Cl. H10P 72/00; B23K 26/53; H10P 10/00; H10P 58/00; B23K 103/00

(52) U.S. Cl. CPC H10P 72/0428; B23K 26/53; H10P 10/12; H10P 58/20; B23K 2103/56

(57) ABSTRACT

Provided is a processing method of a plate-shaped substrate. The substrate processing method includes forming a bonded substrate by bonding one side of the plate-shaped substrate and one side of a support member that supports the substrate to each other as a bonding portion, forming a modified layer inside the substrate by applying a laser beam to the substrate in an annular pattern, and, after the formation of the modified layer, thinning the substrate. The bonded substrate is formed such that, in the bonding portion, a bonding strength in at least part of an outer circumferential region is made lower than a bonding strength in a central region.

### BACKGROUND OF THE INVENTION

### FIELD OF THE INVENTION

The present invention relates to a method for processing a substrate to which a support member is bonded, a method for manufacturing a processed substrate, and a method for manufacturing chips.

### DESCRIPTION OF THE RELATED ART

Device chips to be mounted on electronic equipment such as mobile phones and personal computers are manufactured through processing of semiconductor wafers.

On one side of a semiconductor wafer as a disk-shaped substrate, a plurality of planned dividing lines (streets) are set in a lattice pattern, and such devices as integrated circuits (ICs) and large-scale integration (LSI) circuits are formed in respective rectangular areas partitioned by the planned dividing lines. The semiconductor wafer having the devices formed thereon is

divided into a plurality of device chips by being cut along each planned dividing line.

In recent years, wafers are thinned to make the chips smaller and lighter. For example, in the process of manufacturing device chips as described above, a wafer having devices formed on a face side thereof is thinned in whole by being ground on a reverse side thereof. The thinned wafer is divided to thereby obtain thin device chips.

In such a wafer manufacturing process including thinning processing, in order to maintain the strength of a wafer, a bonded wafer including a wafer to be processed and another member (support member; wafer, for example) being bonded to each other is sometimes used. Grinding processing is performed on the wafer in a state of being bonded to the support member, making it possible to keep a thickness which is sufficient to maintain the strength of the bonded wafer as a whole while the wafer to be processed is thinned.

Incidentally, for conveyance of or processing on a wafer, the wafer is chamfered at an edge portion thereof

in order to prevent, for example, chipping of the wafer during conveyance. When the chamfered wafer is ground and thinned, a thin and pointed shape called a knife edge, for example, is formed at the edge portion of the wafer.

The knife edge formed at the edge portion of the wafer is likely to be chipped. If chipping occurs at the edge portion, the chipping may extend to a device region provided in a central region of the wafer, leading to breakage of the deices. In order to prevent this, processing called edge trimming is effective, for example.

In edge trimming, before a wafer is ground, cutting processing is performed on an outer circumferential region of the wafer, and a chamfered portion provided in the outer circumferential region is removed (refer to Japanese Patent Laid-open No. 2000-173961, for example). Also for a bonded substrate (bonded wafer) including a wafer and a support member such as another substrate being bonded to each other, edge trimming may be performed on the wafer to be processed.

However, there are problems with edge trimming in

that edge trimming itself causes chipping and that devices are contaminated with processing swarf generated in association with cutting. In view of this, especially in the case of a bonded wafer, there has been proposed a technique that forms a modified layer in an outer circumferential region of a wafer to prevent, at the time of grinding, cracks generated in the outer circumferential region from extending to a device region (refer to Japanese Patent Laid-open No. 2020-57709, for example).

### SUMMARY OF THE INVENTION

Extension of cracks is prevented by a modified layer when, as a wafer is ground, the wafer is divided in the vicinity of the fragile modified layer and an outer circumferential region of the wafer is separated. However, in a case where, in a bonded wafer, an outer circumferential region of a wafer is tightly bonded to a support member, such tight bonding reinforces the wafer, and there may arise a problem that division of the wafer at the modified layer and separation of the outer circumferential region are not appropriately realized.

Accordingly, an object of the present invention is to provide a substrate processing method, a processed substrate manufacturing method, and a chip manufacturing method that can appropriately separate an outer circumferential region of a substrate included in a bonded substrate including the substrate and a support member being bonded to each other.

In accordance with an aspect of the present invention, there is provided a processing method of a plate-shaped substrate, the method including forming a bonded substrate by bonding one side of the plate-shaped substrate and one side of a support member that supports the substrate to each other as a bonding portion, forming a modified layer inside the substrate by applying a laser beam to the substrate in an annular pattern, and, after the formation of the modified layer, thinning the substrate, in which the bonded substrate is formed such that, in the bonding portion, a bonding strength in at least part of an outer circumferential region is lower than a bonding strength in a central region.

In accordance with the aspect of the present invention, it is preferable that, before the formation of the bonded substrate or during the formation of the bonded substrate, on at least one of a side that is to be the bonding portion of the substrate or a side that is to be the bonding portion of the support member, bonding strength reduction processing by which, in the bonding portion, the bonding strength in at least part of the outer circumferential region is made lower than the bonding strength in the central region be performed.

In accordance with the aspect of the present invention, in the bonding strength reduction processing, at least part of an outer circumferential region of the side that is to be the bonding portion of the substrate or part of an outer circumferential region of the side that is to be the bonding portion of the support member may be polished or ground.

In accordance with the aspect of the present invention, in the bonding strength reduction processing, on at least one of the side that is to be the bonding portion of the substrate or the side that is to be the bonding portion of the support member, an outer circumferential region may be made rougher than a central region.

In accordance with the aspect of the present invention, in the formation of the bonded substrate, after plasma is applied to at least one of the side that is to be the bonding portion of the substrate or the side that is to be the bonding portion of the support member, the substrate and the support member may be bonded to each other, and the bonding strength reduction processing may be performed by making an application amount of plasma per unit area to an outer circumferential region of the side that is to be the bonding portion of the substrate or an outer circumferential region of the side that is to be the bonding portion of the support member smaller than an application amount of plasma per unit area to a central region.

In accordance with the aspect of the present invention, the bonding strength reduction processing may be performed by causing the side that is to be the bonding portion of the substrate and the side that is to be the bonding portion of the support member to be in contact with each other and pressing the substrate and the support member against each other while pressure applied to an outer circumferential region is made smaller than pressure applied to a central region, thereby bonding the substrate and the support member to each other.

In accordance with the aspect of the present invention, in the formation of the modified layer, the laser beam may be applied in such a manner that a focused spot of the laser beam in the substrate is positioned outward in a radial direction of the substrate as the focused spot approaches the bonding portion in a thickness direction of the substrate.

In accordance with another aspect of the present invention, there is provided a manufacturing method of a processed substrate in a plate shape, the method including manufacturing the processed substrate by use of the substrate processing method described above.

In accordance with a further aspect of the present invention, there is provided a chip manufacturing method using the processed substrate manufacturing method described above, the chip manufacturing method including, after the processed substrate is manufactured, dividing the processed substrate.

In the substrate processing method, the processed substrate manufacturing method, and the chip manufacturing method according to the aspects of the present invention, the substrate and the support member are bonded to each other in such a manner that the bonding strength between the substrate and the support member is made smaller in the outer circumferential region than in the central region, and the modified layer is formed inside the substrate. When the substrate is thinned, a crack extends along the modified layer in the substrate, and the whole or part of the outer circumferential region is separated from the substrate.

Here, in the bonding portion between the substrate and the support member, the bonding strength in the outer circumferential region is made smaller than the bonding strength in the central region, so that, when the whole or part of the outer circumferential region is separated from the substrate, the separated region is easily peeled off from the support member.

As a result, it is possible to appropriately separate the outer circumferential region of the substrate included in the bonded substrate including the substrate and the support member being bonded to each other.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is an exploded perspective view illustrating an example of a bonded substrate (bonded wafer) according to an embodiment;

FIG. 2 is a cross-sectional side view illustrating an example of the bonded substrate (bonded wafer) according to the embodiment;

FIG. 3 is a flowchart describing an example of steps related to a substrate processing method, a processed substrate manufacturing method, and a chip manufacturing method;

FIG. 4 is a side view illustrating a step included in a bonding strength reduction processing step, illustrating a first polishing/grinding step;

FIG. 5 is a side view illustrating a step included in the bonding strength reduction processing step, illustrating a second polishing/grinding step;

FIG. 6 is a side view illustrating a step included in a bonding step;

FIG. 7 is a perspective view illustrating a step included in a modifying step;

FIG. 8 is a cross-sectional side view illustrating the step included in the modifying step;

FIG. 9A is a cross-sectional view schematically illustrating an example of modified layers formed in a substrate (wafer) in the modifying step according to the embodiment;

FIG. 9B is a cross-sectional view schematically illustrating another example of the modified layers formed in the substrate (wafer) in the modifying step according to the embodiment;

FIG. 10 is a side view illustrating a step included in a thinning step, illustrating a state where grinding of the substrate (wafer) is started;

FIG. 11 is a side view illustrating a step included

in the thinning step, illustrating a state where grinding of the substrate (wafer) is advanced;

FIG. 12 is a cross-sectional side view illustrating a step included in a dividing step;

FIG. 13 is a cross-sectional side view illustrating another example of the bonding strength reduction processing step;

FIG. 14 is a cross-sectional side view illustrating still another example of the bonding strength reduction processing step;

FIG. 15 is a cross-sectional side view illustrating yet another example of the bonding strength reduction processing step; and

FIG. 16 is a side view illustrating a further example of the bonding strength reduction processing step.

### DETAILED DESCRIPTION OF THE PREFERRED EMBODIMENT

An embodiment of the present invention will hereinafter be described in detail with reference to the attached drawings.

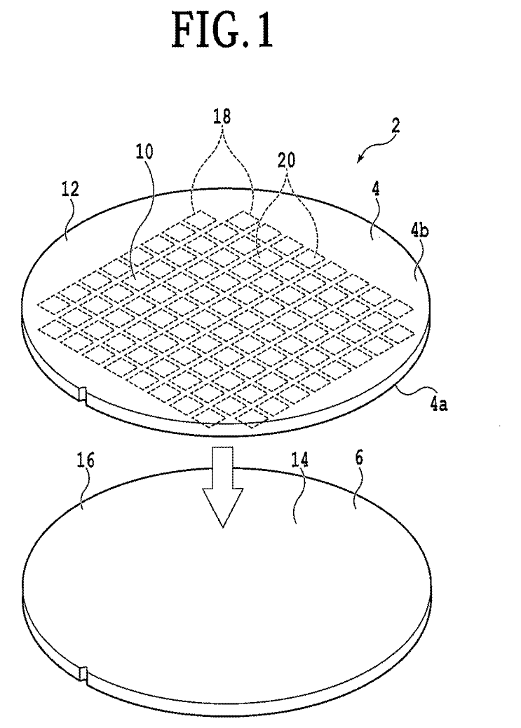

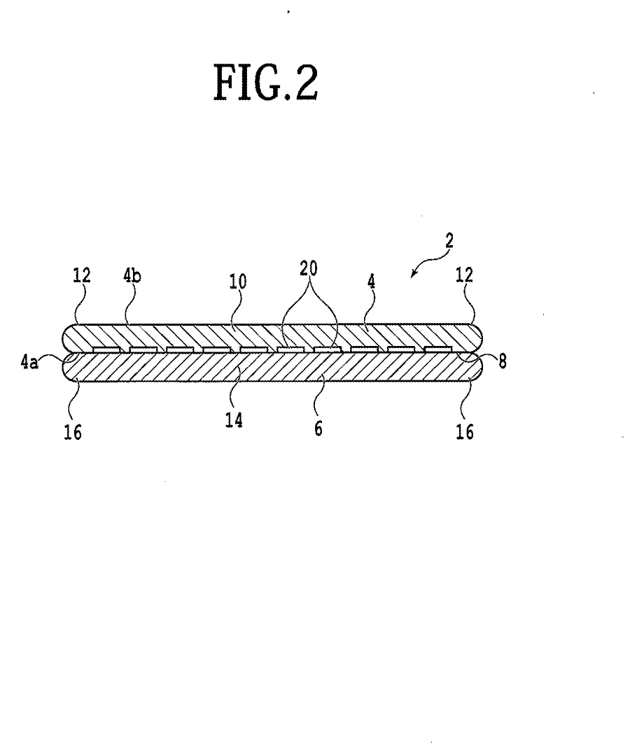

First, with reference to FIGS. 1 and 2, described is a bonded wafer treated in a substrate processing method, a processed substrate manufacturing method, and a chip manufacturing method according to the present embodiment. FIGS. 1 and 2 are an exploded perspective view and a cross-sectional side view that each illustrate an example of the bonded substrate according to the embodiment. A bonded substrate (bonded wafer) 2 has a form in which one side of a plate-shaped substrate (wafer) 4 and one side of a plate-shaped support member 6 are in contact with each other and are bonded to each other. In FIG. 2, a portion where the substrate 4 and the support member 6 are bonded to each other is illustrated as a bonding portion 8.

Note that the "bonding portion" in the present specification is referred to as a portion where members are bonded to each other. In a case where members are directly bonded to each other by a hydrogen bond, for example, the "bonding portion" is referred to as a portion constituting sides where the bonded members are in contact with each other. Further, in a case where members are bonded to each other by an adhesive or the like, for example, the "bonding portion" is referred to as sides of the members bonded to each other by the adhesive or the like.

The substrate 4 is, for example, a disk-shaped wafer formed of such a material as silicon. The substrate (wafer) 4 is, for example, a through-silicon via (TSV) wafer. In the wafer 4, a region (central region) 10 including a central portion is set as a device region (region where devices 20 are formed).

In the wafer 4, no devices 20 are formed in a region that is positioned on a radially outer side and that surrounds the central region (device region) 10. In the present specification, this region is referred to as an outer circumferential region 12. In the wafer 4, the outer circumferential region 12 surrounds the entire circumference of the device region (central region) 10.

Further, in the support member 6 to be bonded to the wafer 4, a region corresponding to the central region 10 of the wafer 4 at the time of bonding is referred to as a central region 14, and a region corresponding to the outer circumferential region 12 of the wafer 4 at the time of bonding is referred to as an outer circumferential region 16.

Note that the central regions 10 and 14 and the outer circumferential regions 12 and 16 of the wafer 4 and the support member 6 can be set as desired according to the dimension, shape, and the like of the device region.

An edge portion as an outermost circumferential portion of the disk-shaped wafer 4 is chamfered and formed in a circular cross-sectional shape such that its central portion in a thickness direction protrudes radially most outwardly.

The device region (central region) 10 is partitioned by a plurality of intersecting planned dividing lines (street) 18 into a plurality of regions. Devices 20 are formed in the respective partitioned regions. Although the devices 20 are each a device constituting a three-dimensional NAND flash memory, for example, the kind of the device is not limited to this.

The devices 20 formed on the wafer 4 which is a TSV wafer each include, for example, an electrode pad (not illustrated) disposed on a front side 4a of the wafer 4 and a rod-shaped electrode member (not illustrated) connected to the electrode pad. On a surface of each of the devices 20, one or more electrode pads are provided.

The electrode member (not illustrated) is embedded in the inside of the wafer 4 in its entirety. One end of the rod-shaped electrode member is connected to a corresponding electrode pad or corresponding electrode pads, while a portion constituting the other end side extends toward a reverse side 4b of the wafer 4.

As the wafer 4 is thinned from the reverse side 4b, the electrode members are exposed on the reverse side 4b of the wafer 4. Further, when the wafer 4 is divided into device chips including the respective devices 20, the electrode members become TSVs that penetrate substrates of the devices 20.

The wafer 4 that has been thinned tends to be reduced in rigidity, causing such problems as cracks and chipping. In order to prevent this, the wafer 4 is treated as the bonded wafer 2 including the wafer 4 and the support member 6 being bonded to each other, as illustrated in FIGS. 1 and 2.

The support member 6 is a TSV wafer in a form equivalent to that of the wafer 4, for example, and has devices formed on one side (front side) thereof. In a case where the support member 6 is a wafer having devices formed on one side (front side) thereof, the wafer 4 and the support member 6 are bonded to each other at the sides (front sides) on which devices are formed, for example.

The one side (front side) of the support member 6 and the front side 4a of the wafer 4 are directly bonded to each other by a hydrogen bond, for example. Note that the wafer 4 and the support member 6 are bonded to each other not necessarily directly by a hydrogen bond. The bonding between them can be realized by various principles and methods. For example, they may be bonded to each other by an adhesive, an adhesive tape, or the like.

There are no limitations on the kinds, materials, shapes, structures, and sizes, for example, of the substrate 4 and the support member 6. The substrate 4 and the support member 6 may each be a substrate (wafer) including such a material as a semiconductor other than silicon (GaAs, InP, GaN, or SiC, for example), sapphire, glass, ceramic, resin, or metal, for example. Further, there are no limitations on the kinds, numbers, shapes, structures, sizes, and layouts, for example, of the devices 20 formed on the wafer 4 and the support member 6. At least any one of the wafer 4 or the support member 6 may be free of the devices 20.

For example, the support member 6 may be what is generally called a dummy wafer called a non-product (NP) wafer, a quality control (QC) wafer, or the like. In a case where the support member 6 is a dummy wafer, no devices are formed on the support member 6.

The substrate 4 and the support member 6 may include the same material or different materials. Further, the substrate 4 and the support member 6 may be formed in the same shape or different shapes. Moreover, there is no limitation on the shape of the support member 6, and the support member 6 may have any shape that is capable of being bonded to the substrate 4 and supporting the substrate 4. However, the support member 6 preferably has the size and shape capable of supporting the entire substrate 4.

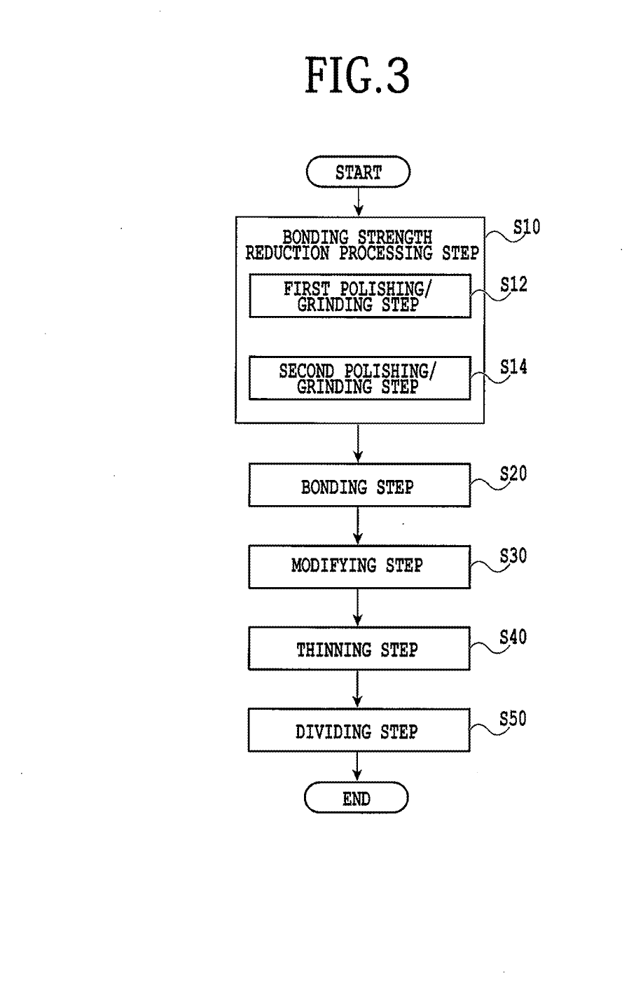

Next, steps related to processing or the like on the above-described bonded substrate (bonded wafer) 2 is described. FIG. 3 is a flowchart describing an example of steps related to a substrate (wafer) processing method, a processed substrate (processed wafer) manufacturing method, and a chip manufacturing method.

Steps illustrated in FIG. 3 include bonding strength reduction processing step S10, bonding step S20, modifying step S30, thinning step S40, and dividing step S50.

In bonding strength reduction processing step S10, on at least one of a side that is to be the bonding portion 8 of the substrate (wafer) 4 or a side that is to be the bonding portion 8 of the support member 6, processing by which, in the bonding portion 8 after bonding has been performed, the bonding strength in at least part of the outer circumferential region 12 or 16 is made lower than the bonding strength in the central region 10 or 14 is performed.

Here, the "processing by which the bonding strength in at least part of the outer circumferential region 12 or 16 is made lower than the bonding strength in the central region 10 or 14" refers to processing by which, when thinning step S40 is performed on the bonded wafer 2 having been subjected to modifying step S30, in the wafer 4 bonded to the support member 6 at the bonding portion 8, a portion corresponding to the central region (device region) 10 becomes relatively difficult to be peeled off from the support member 6 while a portion corresponding to the outer circumferential region 12 becomes relatively easy to be peeled off from the support member 6.

Alternatively, the "processing by which the bonding strength in at least part of the outer circumferential region 12 or 16 is made lower than the bonding strength in the central region 10 or 14" refers to processing by which the bonding strength in the outer circumferential region 12 is made low compared to a case where such processing is not performed.

More specifically, for example, performed in bonding strength reduction processing step S10 is processing by which force per unit area necessary for peeling off the portion corresponding to the central region 10 of the wafer 4 from the portion corresponding to the central region 14 of the support member 6 is made larger than force per unit area necessary for peeling off the portion corresponding to the outer circumferential region 12 of the wafer 4 from the portion corresponding to the outer circumferential region 16 of the support member 6.

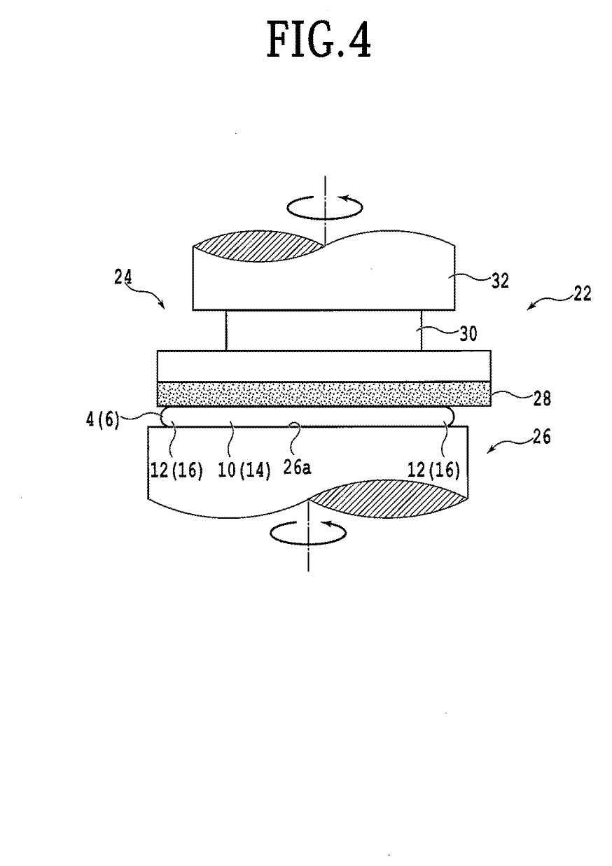

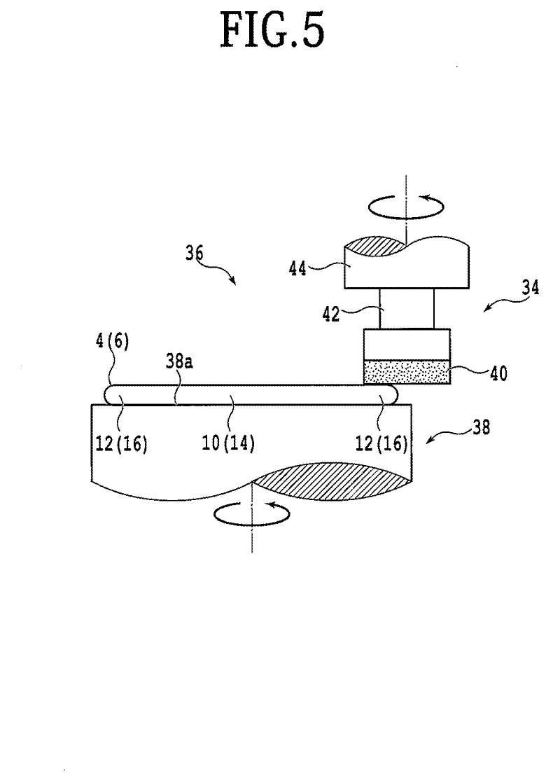

Bonding strength reduction processing step S10 includes first polishing/grinding step S12 and second polishing/grinding step S14, for example, as illustrated in FIG. 3. FIGS. 4 and 5 are side views illustrating steps included in bonding strength reduction processing step S10 and illustrate first polishing/grinding step S12 and second polishing/grinding step S14, respectively.

In first polishing/grinding step S12, a first polishing apparatus 22 polishes the wafer 4 or the support member 6. Polishing is performed, in the wafer 4 or the support member 6, on the side that is to be the bonding portion 8 (see FIG. 2) after bonding has been performed. Polishing in first polishing/grinding step S12 may be performed on one of the wafer 4 and the support member 6 or may be performed on both the wafer 4 and the support member 6.

The first polishing apparatus 22 includes a first polishing unit 24 and a holding mechanism 26.

The first polishing unit 24 includes a spindle 30 to which a polishing pad 28 is attached and a housing 32 in which the spindle 30 is rotatably supported. The spindle 30 is formed in a cylindrical shape and supported in the housing 32 in such a posture that its axis is along a vertical direction. To a lower end portion of the spindle 30, the polishing pad 28 is attached, and to an upper end portion of the spindle 30, an unillustrated rotary drive source such as a motor is attached. When the rotary drive source is operated, the spindle 30 rotates with its axis along the vertical direction as a center together with the polishing pad 28.

The holding mechanism 26 is a chuck table, for example, and holds the wafer 4 or the support member 6 as a target under suction. An upper surface 26a of the holding mechanism 26 is a holding surface that holds the wafer 4 or the support member 6. On the holding surface (upper surface) 26a, negative pressure is supplied from an unillustrated suction source, so that the wafer 4 or the support member 6 as a target is attracted under suction on the holding surface 26a. To a lower portion of the holding mechanism 26, a rotation mechanism (not illustrated) that rotates the holding mechanism 26 with a rotational axis along the vertical direction as a center is coupled.

In the vicinity of the holding surface 26a, an unillustrated nozzle (processing liquid supply unit) is provided, and processing liquid necessary for polishing, such as water or slurry, is supplied from the nozzle. Note that the processing liquid may be supplied via a flow channel (not illustrated) provided inside the first polishing unit 24, for example.

In first polishing/grinding step S12, as illustrated in FIG. 4, for example, the wafer 4 or the support member 6 as a polishing target is polished by the first polishing unit 24 including the spindle 30 to which the polishing pad 28 having a diameter that is the same as or equal to or larger than the width (dimension in a direction perpendicular to a thickness direction) of the wafer 4 or the support member 6 is attached.

The wafer 4 or the support member 6 as a polishing target is held by the holding mechanism 26 in such a manner that a side to be polished faces upward (the first polishing unit 24 side) and the opposite side is in contact with the holding surface 26a.

In a state where the spindle 30 is positioned above the holding mechanism 26, while the spindle 30 rotates with a rotational axis along the vertical direction as the center together with the polishing pad 28, the holding mechanism 26 rotates with the rotational axis along the vertical direction as the center together with the wafer 4 or the support member 6. When the polishing pad 28 comes into contact with the wafer 4 or the support member 6, the wafer 4 or the support member 6 is polished.

At the time of polishing, such liquid as water or slurry as processing liquid is supplied as appropriate from the unillustrated nozzle (processing liquid supply unit) described above.

Next, second polishing/grinding step S14 is performed. In second polishing/grinding step S14, in the wafer 4 or the support member 6 as a polishing target, part of the side that is to be the bonding portion 8 after bonding has been performed is polished by a second polishing apparatus 34. A region to be polished is at least part of the outer circumferential region 12 or 16 of the wafer 4 or the support member 6.

The second polishing apparatus 34 includes a second polishing unit 36 and a holding mechanism 38.

The second polishing unit 36 includes a spindle 42 to which a polishing pad 40 is attached and a housing 44 in which the spindle 42 is rotatably supported. The spindle 42 is formed in a cylindrical shape and supported in the housing 44 in such a posture that its axis is along the vertical direction. To a lower end portion of the spindle 42, the polishing pad 40 is attached, and to an upper end portion of the spindle 42, an unillustrated rotary drive source such as a motor is attached. When the rotary drive source is operated, the spindle 42 rotates with its axis along the vertical direction as a center together with the polishing pad 40.

The holding mechanism 38 is a chuck table, for example, and holds the wafer 4 or the support member 6 as a target under suction. An upper surface 38a of the holding mechanism 38 is a holding surface that holds the wafer 4 or the support member 6. On the holding surface (upper surface) 38a, negative pressure is supplied from an unillustrated suction source, so that the wafer 4 or the support member 6 as a target is attracted under suction on the holding surface 38a. To a lower portion of the holding mechanism 38, a rotation mechanism (not illustrated) that rotates the holding mechanism 38 with a rotational axis along the vertical direction as a center is coupled.

In the vicinity of the holding surface 38a, an unillustrated nozzle (processing liquid supply unit) is provided, and processing liquid necessary for polishing, such as water or slurry, is supplied from the nozzle. Note that the processing liquid may be supplied via a flow channel (not illustrated) provided inside the second polishing unit 36, for example.

In second polishing/grinding step S14, as illustrated in FIG. 5, for example, the wafer 4 or the support member 6 as a polishing target is polished by the second polishing unit 36 including the spindle 42 to which the polishing pad 40 having a diameter sufficiently smaller than the width of the wafer 4 or the support member 6 is attached.

The wafer 4 or the support member 6 as a polishing target is held by the holding mechanism 38 in such a manner that a side to be polished faces upward (the second polishing unit 36 side) and the opposite side is in contact with the holding surface 38a. In a state where the spindle 42 is positioned above the holding mechanism 38, while the spindle 42 rotates with a rotational axis along the vertical direction as the center together with the polishing pad 40, the holding mechanism 38 rotates with the rotational axis along the vertical direction as the center together with the wafer 4 or the support member 6.

In second polishing/grinding step S14, the polishing pad 40 comes into contact with the outer circumferential region 12 or 16 of the wafer 4 or the support member 6. For example, in a state where the second polishing unit 36 is positioned with respect to the holding mechanism 38 in such a manner that the rotational axis of the spindle 42 to which the polishing pad 40 having a small diameter is attached overlaps the outer circumferential region 12 or 16 of the wafer 4 or the support member 6 in a plan view, the spindle 42 and the holding mechanism 38 rotate, and the polishing pad 40 comes into contact with the outer circumferential region 12 or 16 of the wafer 4 or the support member 6, thereby polishing the outer circumferential region 12 or 16.

At the time of polishing, such liquid as water or slurry as processing liquid is supplied as appropriate from the unillustrated nozzle (processing liquid supply unit) described above.

In this manner, in second polishing/grinding step S14, the outer circumferential region 12 or 16 of the wafer 4 or the support member 6 is polished, so that such a shape that the outer circumferential region 12 or 16 is slightly recessed in the thickness direction with respect to the central region 10 or 14 (such a shape that the central region 10 or 14 slightly protrudes with respect to the outer circumferential region 12 or 16) is obtained. As a result, when the wafer 4 and the support member 6 are bonded to each other, the degree of adhesion between the wafer 4 and the support member 6 in the outer circumferential regions 12 and 16 is made smaller than the degree of adhesion between the wafer 4 and the support member 6 in the central regions 10 and 14, so that the bonding strength in the outer circumferential regions 12 and 16 is reduced.

Note that, when the outer circumferential region 12 or 16 is polished in second polishing/grinding step S14, it is unnecessary to polish the whole of the outer circumferential region 12 of the wafer 4 or the outer circumferential region 16 of the support member 6, and it is sufficient if at least part of the outer circumferential region 12 or the outer circumferential region 16 is polished. The region that is polished can include, for example, a portion that is opposite to a notch (cutout) indicative of the crystal orientation and a portion including a shape for a mark.

The wafer 4 and the support member 6 are bonded to each other to form the bonded wafer 2 as illustrated in FIG. 2. As processing steps are performed thereafter, outer circumferential portions are peeled off from each other. The peel-off is performed by causing such liquid as water to enter a space between the outer circumferential regions 12 and 16 of the wafer 4 and the support member 6. At this time, it is easy for liquid to enter a portion at which a notch is formed, so that such a portion is used as a peel-off initiating point in many cases.

In a case where the peel-off is performed with a notch as an initiating point, a peeling defect is likely to occur at a portion that is opposite to the notch. In order to prevent the occurrence of a peeling defect, it is effective to polish the side opposite to the notch in the outer circumferential region 12 and/or the outer circumferential region 16 to reduce the bonding strength in this portion in advance.

Further, a shape (ID) for a mark is formed in the wafer 4 and/or the support member 6 in some cases. In a region in which an ID is formed, formation of a modified layer in modifying step S30 may be insufficient due to the presence of the ID, increasing a possibility of occurrence of a peeling defect. In view of this, a portion which is part of the outer circumferential region 12 and/or the outer circumferential region 16 and in which the ID is formed is polished to reduce the bonding strength in this portion, making it possible to prevent the occurrence of a peeling defect caused by insufficient formation of the modified layer.

In another case, there may be a region in which cracks are difficult to extend in the wafer 4 and/or the support member 6, depending on the crystal orientation, for example. It can be assumed that, in such a region, cracks are difficult to extend from the modified layer and a peeling defect is thereby likely to occur. In a case where such a region is present in the outer circumferential region 12 and/or the outer circumferential region 16, this region is polished to reduce the bonding strength, making it possible to prevent the occurrence of a peeling defect caused by difficulty in extension of cracks.

In a case where only part of the outer circumferential region 12 of the wafer 4 or only part of the outer circumferential region 16 of the support member 6 is polished in second polishing/grinding step S14, polishing is performed without rotation of the holding mechanism 38.

Note that, although a case where different polishing apparatuses (the first polishing apparatus 22 and the second polishing apparatus 34) are used in first polishing/grinding step S12 and second polishing/grinding step S14, respectively, is described here as an example, one apparatus including a plurality of polishing units may perform first polishing/grinding step S12 and second polishing/grinding step S14, for example. Alternatively, one apparatus including one polishing unit may perform first polishing/grinding step S12 and second polishing/grinding step S14 by replacing a polishing pad with another polishing pad.

Further alternatively, first polishing/grinding step S12 and second polishing/grinding step S14 may be performed by the same polishing unit and polishing pad with changes in relative position, movement, and the like of the polishing unit and the holding mechanism at the time of polishing.

Also with regard to the holding mechanism (chuck table), a case where different holding mechanisms are used in first polishing/grinding step S12 and second polishing/grinding step S14 is described here. However, first polishing/grinding step S12 and second polishing/grinding step S14 may successively be performed in a state where the wafer 4 or the support member 6 is held by the same holding mechanism.

Further, first polishing/grinding step S12 and second polishing/grinding step S14 may be performed on the wafer 4 and the support member 6 or may be performed on only one of the wafer 4 and the support member 6.

Moreover, first polishing/grinding step S12 may be performed on both the wafer 4 and the support member 6 while second polishing/grinding step S14 may be performed on only one of the wafer 4 and the support member 6, or first polishing/grinding step S12 may be performed on only one of the wafer 4 and the support member 6 while second polishing/grinding step S14 may be performed on both the wafer 4 and the support member 6. Alternatively, first polishing/grinding step S12 may be performed on only one of the wafer 4 and the support member 6 while second polishing/grinding step S14 may be performed on only the other.

Further alternatively, for example, in a case where the side that is to be the bonding portion 8 is sufficiently smooth even if polishing or grinding is not performed, first polishing/grinding step S12 may be omitted.

Any one of first polishing/grinding step S12 and second polishing/grinding step S14 may be performed first. For example, on one of the wafer 4 and the support member 6, first polishing/grinding step S12 may be performed after second polishing/grinding step S14 is performed.

As described above, in bonding strength reduction processing step S10 including first polishing/grinding step S12 and second polishing/grinding step S14 illustrated in FIGS. 4 and 5, the bonding strength in the portion that is to be the bonding portion 8 (see FIG. 2) in the wafer 4 or the support member 6 is adjusted by polishing.

Here, in at least part of first polishing/grinding step S12 and second polishing/grinding step S14, the bonding strength may be adjusted by grinding by grindstones in place of or in addition to polishing by the polishing pad.

Grinding by grindstones is performed by a grinding apparatus including a grinding unit, for example. The grinding unit includes a spindle to which a grinding wheel is attached. The grinding wheel is a disk-shaped component including a plurality of grindstones provided on one side thereof along a circumferential direction, and is rotated by rotation of the spindle. When the grinding wheel is rotated, grindstones rotate along an annular track. The rotating grindstones come into contact with the wafer 4 or the support member 6 held by the holding mechanism, thereby grinding the wafer 4 or the support member 6.

For example, the whole of the portion that is to be the bonding portion 8 in the wafer 4 or the support member 6 is first polished by the polishing pad (first polishing/grinding step S12), and the outer circumferential region 12 or 16 is thereafter ground. As a result, a portion constituting the outer circumferential region 12 or 16 of the wafer 4 or the support member 6 is ground by an amount greater than that in a portion constituting the central region 10 or 14, so that the bonding strength in the outer circumferential region 12 or 16 is reduced.

Alternatively, as a result of grinding by abrasive grains of grindstones, the degree of smoothness of a surface of the portion constituting the outer circumferential region 12 or 16 is reduced, causing decline in contact area between the wafer 4 and the support member 6 and reduction of the bonding strength in the outer circumferential region 12 or 16. Further alternatively, the portion constituting the outer circumferential region 12 or 16 is roughened, so that the amount of deformation necessary for adhesion between the wafer 4 and the support member 6 in this portion is increased, and the bonding strength in the outer circumferential region 12 or 16 is reduced.

For example, another method such as blasting on the outer circumferential region 12 or 16 of the wafer 4 or the support member 6 or polishing the outer circumferential region 12 or 16 while supplying slurry including abrasive grains with a large grain size can also reduce the bonding strength in the outer circumferential region 12 or 16.

As described above, bonding strength reduction processing step S10 can also be performed by making the outer circumferential region 12 or 16 rougher than the central region 10 or 14 on at least one of the side that is to be the bonding portion 8 of the wafer 4 or the side that is to be the bonding portion 8 of the support member 6.

Next, bonding step S20 is performed. In bonding step S20, one side of the wafer 4 and one side of the support member 6 that supports the wafer 4 are bonded to each other as the bonding portion 8.

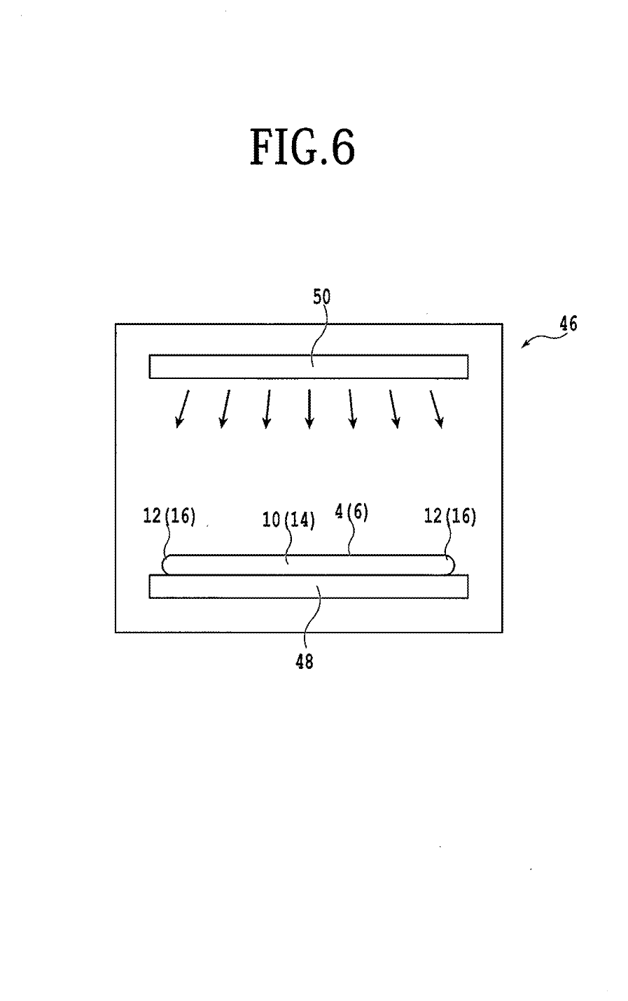

Bonding step S20 is performed by, for example, applying plasma to the side that is to be the bonding portion 8 of the wafer 4 or the support member 6 and thereafter adhering the wafer 4 and the support member 6 to each other. FIG. 6 is a side view illustrating a step (plasma processing) included in bonding step S20. A plasma processing apparatus 46 is used for application of plasma.

The plasma processing apparatus 46 includes a first electrode 48 and a second electrode 50 in a chamber. The first electrode 48 is formed also as a stage that supports the wafer 4 or the support member 6 as a processing target. The second electrode 50 is provided above the first electrode 48.

At the time of plasma processing, the wafer 4 or the support member 6 as a processing target is placed on the first electrode 48 such that the side to be processed (side that is to be the bonding portion 8) faces upward (the front side, the second electrode 50 side) and the opposite side comes in contact with the upper surface of the first electrode 48. In this state, a voltage is applied to a space between the first electrode 48 and the second electrode 50, and gas that is present between the first electrode 48 and the second electrode 50 is ionized. At this time, as appropriate, the space between the first electrode 48 and the second electrode 50 is depressurized, or a specific kind of gas is supplied to this space.

Part of plasma produced by ionization of the gas is applied to the wafer 4 or the support member 6 placed on the first electrode 48, and a material constituting the side that is to be the bonding portion 8 of the wafer 4 or the support member 6 is activated.

The plasma processing described above is performed on one of the wafer 4 and the support member 6 or both the wafer 4 and the support member 6, which are to be bonded to each other. Water is supplied to the activated side as appropriate, and a hydroxyl group (OH group) is formed. Thereafter, the wafer 4 and the support member 6 are adhered to be bonded to each other as illustrated in FIG. 1, and the bonded wafer 2 illustrated in FIG. 2 is formed.

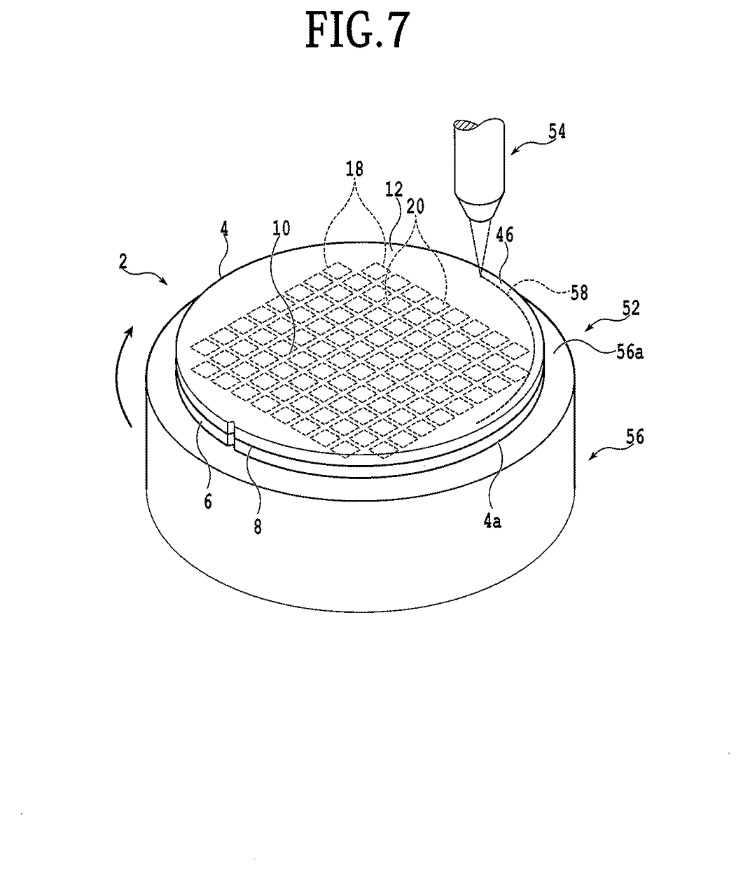

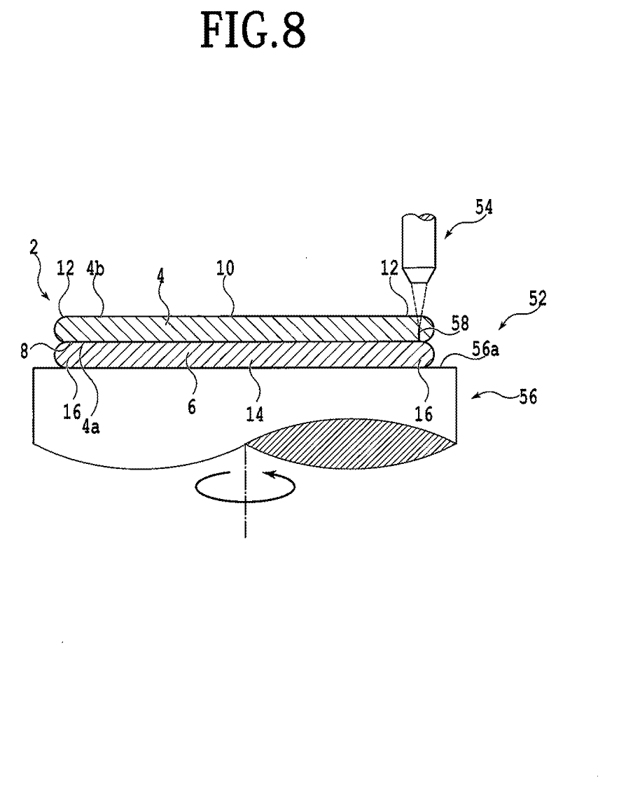

Next, a modified layer is formed by a laser beam in the wafer 4 that is part of the bonded wafer 2 and that is to be processed (modifying step S30). FIGS. 7 and 8 are a perspective view and a cross-sectional side view, respectively, that illustrate an example of a manner in which modifying step S30 is performed.

In modifying step S30, a laser processing apparatus 52 illustrated in FIGS. 7 and 8 is used, for example. The laser processing apparatus 52 includes an irradiation unit 54 that applies a laser beam to the bonded wafer 2 and a holding mechanism 56 that holds the bonded wafer 2.

The irradiation unit 54 is a mechanism that guides and focuses the laser beam emitted from an unillustrated laser oscillator, by an optical system including optical elements such as a mirror and a lens, which are not illustrated, and applies the laser beam to the bonded wafer 2 held by the holding mechanism 56.

The holding mechanism 56 is a chuck table, for example, and holds the bonded wafer 2 as a target under suction. An upper surface 56a of the holding mechanism 56 is a holding surface that holds the bonded wafer 2. On the holding surface 56a, negative pressure is supplied from an unillustrated suction source, so that the bonded wafer 2 as a target is attracted under suction on the holding surface 56a. To a lower portion of the holding mechanism 56, a rotation mechanism (not illustrated) that rotates the holding mechanism 56 with a rotational axis along the vertical direction as a center is coupled.

In modifying step S30, the bonded wafer 2 is held on the holding surface 56a of the holding mechanism 56 and irradiated with a laser beam having a wavelength that is less likely to be absorbed by the wafer 4 (wavelength transmittable through a material constituting the wafer 4) of the bonded wafer 2. The laser beam is applied after being adjusted such that a focused spot of the laser beam is at an intended position in the wafer 4 by use of a focusing lens provided in the irradiation unit 54.

As illustrated in FIGS. 7 and 8, the laser beam is applied from the irradiation unit 54 positioned above the holding mechanism 56 to the outer circumferential region 12 of the wafer 4 which is positioned below the irradiation unit 54. Application of the laser beam and rotation of the holding mechanism 56 are carried out at the same time, so that the laser beam is applied to the wafer 4 in an annular pattern.

Inside (in the vicinity of the focused spot in) the wafer 4 that has been irradiated with the laser beam, on the radially outer side of the central region (device region) 10, a modified layer 58 is formed in an annular pattern in such a manner as to surround the central region 10. The modified layer 58 is positioned closer to the front side 4a (side on which devices 20 are formed) in the thickness direction of the wafer 4.

The laser beam may be branched by optical elements such as a diffractive optical element (DOE) and a liquid crystal on silicon (LCoS), for example, and applied to the wafer 4.

Note that the modified layer refers to a region in which the density, refractive index, mechanical strength, or any other physical property has changed to be different from that of the surrounding base material. Specifically, the modified layer is a region that has been subjected to a melting treatment, a region having cracks, a region that has been dielectrically broken down, a region whose refractive index is different from that of other regions, region in which these regions are mixed, or the like, for example. The modified layer is lower in mechanical strength than the other regions, for example.

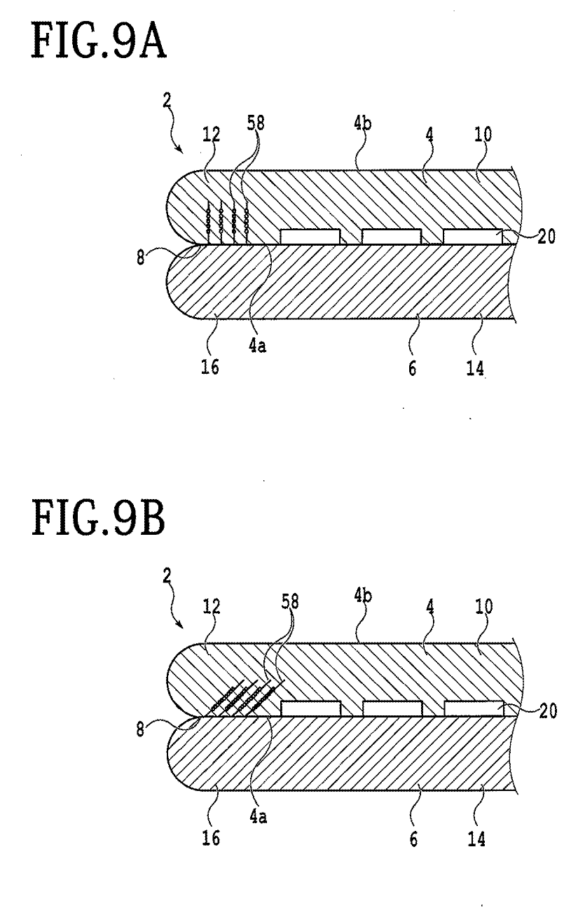

FIGS. 9A and 9B are each a cross-sectional view schematically illustrating an example of modified layers 58 formed in the wafer 4 in modifying step S30 according to the embodiment.

In the example illustrated in FIG. 9A, a plurality of modified layers 58 are each formed in such a manner as to extend along the thickness direction of the wafer 4. Since the modified layers 58 are formed in an annular pattern as illustrated in FIGS. 7 and 8, the modified layers 58 are distributed in such a manner as to be along a cylindrical surface as a whole.

In the example illustrated in FIG. 9B, a plurality of modified layers 58 are each formed in such a manner as to extend obliquely with respect to the thickness direction of the wafer 4. As described above, the modified layers 58 are each formed in the vicinity of the front side 4a in the thickness direction of the wafer 4. As illustrated in FIG. 9B, the modified layers 58 extending obliquely with respect to the thickness direction are formed in such a manner as to be positioned outward in a radial direction of the wafer 4 as they approach the front side 4a of the wafer 4. That is, the modified layers 58 are distributed in such a manner as to be along a conical surface as a whole.

In order to form the modified layers 58 in such a form, in modifying step S30, the laser beam is applied in such a manner that the focused spot of the laser beam in the wafer 4 is positioned outward in the radial direction of the wafer 4 as the focused spot approaches the side (front side 4a) that is to be the bonding portion 8 in the thickness direction of the wafer 4.

The thickness of the region where the modified layers 58 are formed in the wafer 4 is preferably at least half or more of a finish thickness of the wafer 4 in thinning step S40 that follows modifying step S30, and is more preferably equal to or greater than the finish thickness. When the thickness of the region where the modified layers 58 are formed is set as described above, in thinning step S40, cracks extend from or in the vicinity of the modified layers 58, making it easier to remove the region (outer circumferential region 12) positioned on the radially outer side of the modified layers 58 in the wafer 4.

Here, as illustrated in FIGS. 9A and 9B, the plurality of modified layers 58 are formed concentrically with each other, making it possible to adjust the width (dimension in a radial direction) of the region to be removed from the wafer 4 in thinning step S40 and the width of the region in which cracks are formed.

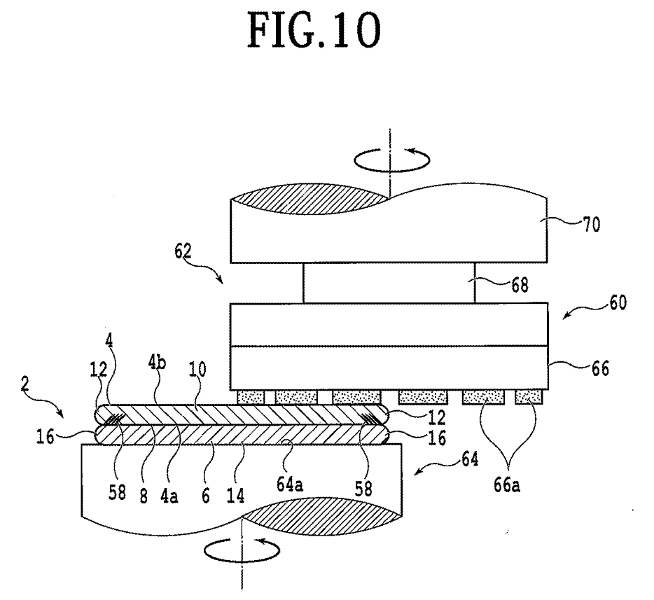

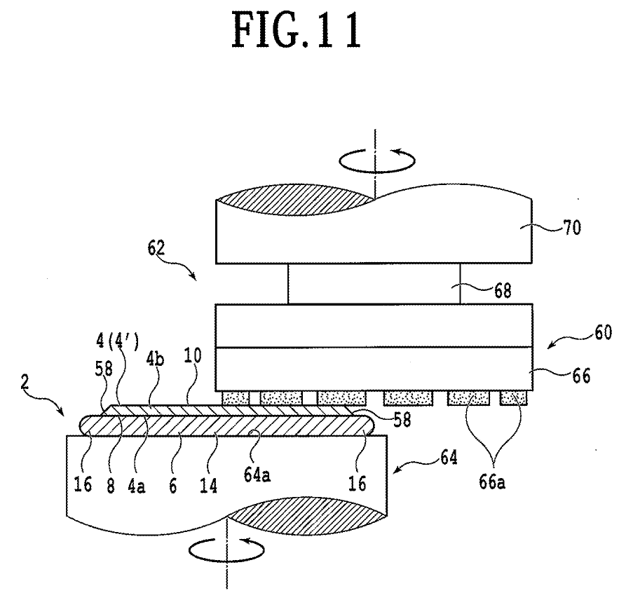

Subsequently, thinning step S40 is performed. FIGS. 10 and 11 are side views each illustrating a step included in thinning step S40. FIG. 10 illustrates a state where grinding of the wafer 4 is started, and FIG. 11 illustrates a state where grinding of the wafer 4 is advanced.

In thinning step S40, a grinding apparatus 60 illustrated in FIGS. 10 and 11 is used, for example, and grinds the wafer 4 from the reverse side 4b. The grinding apparatus 60 includes a grinding unit 62 and a holding mechanism 64.

The grinding unit 62 includes a spindle 68 to which a grinding wheel 66 is attached and a housing 70 in which the spindle 68 is rotatably supported. The spindle 68 is formed in a cylindrical shape and supported in the housing 70 in such a posture that its axis is along the vertical direction. To a lower end portion of the spindle 68, a wheel mount to which the grinding wheel 66 is attached is provided, and to an upper end portion of the spindle 68, an unillustrated rotary drive source such as a motor is attached.

The grinding wheel 66 is a disk-shaped component including a plurality of grindstones 66a provided on one side thereof along the circumferential direction. The grinding wheel 66 is attached to the wheel mount provided to the lower end portion of the spindle 68, in such a manner that a side on which the grindstones 66a are provided faces downward. When the unillustrated rotary drive source attached to the spindle 68 is operated, the spindle 68 rotates with its axis along the vertical direction as a center together with the grinding wheel 66.

The holding mechanism 64 is a chuck table, for example, and holds the bonded wafer 2 as a target under suction. An upper surface 64a of the holding mechanism 64 is a holding surface that holds the bonded wafer 2. On the holding surface 64a, negative pressure is supplied from an unillustrated suction source, so that the bonded wafer 2 as a target is attracted under suction on the holding surface 64a. To a lower portion of the holding mechanism 64, a rotation mechanism (not illustrated) that rotates the holding mechanism 64 with a rotational axis along the vertical direction as a center is coupled.

In the vicinity of the holding surface 64a, an unillustrated nozzle (processing liquid supply unit) is provided, and processing liquid necessary for polishing, such as water or slurry, is supplied from the nozzle. Note that the processing liquid may be supplied via a flow channel (not illustrated) provided inside the grinding unit 62, for example.

In thinning step S40, as illustrated in FIG. 10, the bonded wafer 2 is held by the holding mechanism 64 in such a manner that the reverse side 4b of the wafer 4 faces upward (the grinding unit 62 side) and the support member 6 is in contact with the holding surface 64a.

In a state where the spindle 68 is positioned above the holding mechanism 64, while the spindle 68 rotates with a rotational axis along the vertical direction as the center together with the grinding wheel 66, the holding mechanism 64 rotates with the rotational axis along the vertical direction as the center together with the bonded wafer 2. When the grinding wheel 66 and the wafer 4 come into contact with each other, the wafer 4 is ground from the reverse side 4b. At the time of grinding, such liquid as water or slurry as processing liquid is supplied as appropriate from the unillustrated nozzle (processing liquid supply unit) described above.

When grinding is advanced and, owing to the grinding, the position of the reverse side 4b reaches a modified layer 58 formed in the wafer 4 or a crack extending from the modified layer 58, the outer circumferential region 12 positioned on the radially outer side of the modified layer 58 in the wafer 4 is removed, as illustrated in FIG. 11.

At the time of grinding, the grinding wheel 66 and the holding mechanism 64 apply force to the wafer 4 from above and below, and the wafer 4 and the grindstones 66a slide. As a result, pressure is generated inside the wafer 4, a crack extends along the modified layer 58 by this pressure, and the whole or part of the outer circumferential region 12 is separated from the wafer 4.

Here, processing by which the bonding strength in at least part of the outer circumferential region 12 or 16 is made lower than the bonding strength in the central region 10 or 14 has been performed in the bonding portion 8 between the wafer 4 and the support member 6 in bonding strength reduction processing step S10. Accordingly, when the whole or part of the outer circumferential region 12 is separated from the wafer 4 by the modified layer 58, the separated region is easily peeled off from the support member 6. In this manner, separation of the whole or part of the outer circumferential region 12 from the wafer 4 is carried out.

Here, when the modified layers 58 are formed in a conical surface shape as illustrated in FIG. 9B, at the time of forming the modified layers 58 in modifying step S30 or removing the outer circumferential region 12 in thinning step S40, for example, cracks extending from the modified layers 58 are less likely to reach the devices 20 formed in the device region 10 on the front side 4a.

In contrast to the example illustrated in FIG. 9B, a state where the modified layers are formed from the front side 4a to the reverse side 4b in an inverted conical shape (shape in which the modified layers are positioned on the radially outer side as they approach the reverse side 4b) is assumed. If the modified layers are formed in such a shape, the reverse side 4b in the device region 10 protrudes on the radially outer side with a gap formed between the protruding portion and an upper surface of the support member 6 after the outer circumferential region 12 is separated, so that chipping may be likely to occur.

Further, in the case where the modified layers are formed in an inverted conical shape, a region that is part of the outer circumferential region 12 and that is on the lower side (front side 4a) with respect to the modified layers formed obliquely is of a shape that becomes thinner on a radially inner side, so that this region may be cracked when the outer circumferential region 12 is peeled off along the modified layers, and part of the outer circumferential region 12 may be likely to remain bonded to the support member 6.

When the modified layers 58 are formed in a right circular conical shape from the front side 4a to the reverse side 4b as illustrated in FIG. 9B, it is assumed that the problems described above are less likely to arise.

While damage to the devices 20 is prevented as described above, the outer circumferential region 12 is removed appropriately as the wafer 4 is ground, and a processed wafer 4' from which the outer circumferential region 12 has been removed can be obtained.

Note that, in a case where the whole or part of the outer circumferential region 12 of the wafer 4 remains bonded to the support member 6 in thinning step S40, a peeling step may be performed separately to peel off the whole or part of the outer circumferential region 12 of the wafer 4 from the support member 6. In the peeling step, the whole or part of the outer circumferential region 12 of the wafer 4 is peeled off from the support member 6 by such a method as ultrasonication, supply of fluid such as water to the bonding portion 8, or application of an external force, for example.

Further, the wafer 4 may be thinned in thinning step S40 by, instead of or in addition to the above-described grinding using the grinding apparatus 60, such a method as cutting using a cutting apparatus, for example. The cutting apparatus includes, for example, a cutting unit and a holding mechanism.

The cutting unit includes a spindle to which a cutting blade is attached and a housing in which the spindle is rotatably supported. The cutting blade includes, for example, an annular base and an annular cutting edge mounted on the base along an outer circumferential edge of the base.

The spindle is formed in a cylindrical shape and includes on one end thereof a blade mounter to which the cutting blade is mounted and on the other end thereof a rotary drive source such as a motor. The spindle in a cylindrical shape is housed in the housing in such a manner that its axis is along a horizontal direction, and rotates with its axis along the horizontal direction as a center together with the cutting blade when the rotary drive source is operated.

At the time of cutting, the bonded wafer 2 is held by the holding mechanism in such a manner that the reverse side 4b of the wafer 4 faces upward (the cutting unit side), and the cutting blade cuts into the wafer 4 from the reverse side 4b while rotating together with the spindle. While the cutting blade is cutting into the wafer 4, the cutting unit and the holding mechanism are moved relative to each other in a direction along a holding surface, thereby thinning the wafer 4 from the reverse side 4b.

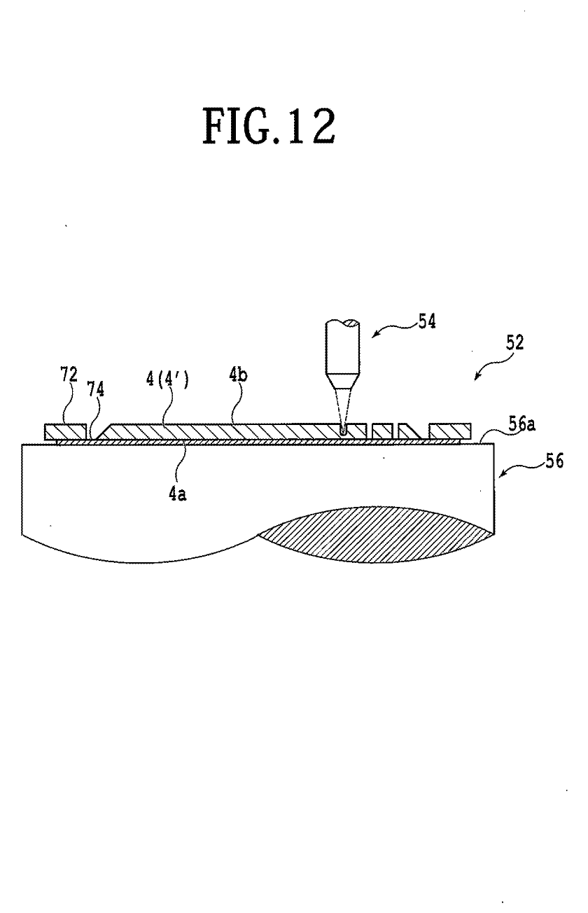

The substrate (wafer) 4 is thinned in this manner, the processed substrate (processed wafer) 4' is manufactured, and thereafter, dividing step S50 is performed on the processed wafer 4'. FIG. 12 is a cross-sectional side view illustrating an example of a manner in which dividing step S50 is performed. Dividing step S50 can be performed, as in modifying step S30 (see FIG. 8), by use of the laser processing apparatus 52 including the irradiation unit 54 and the holding mechanism 56.

In the example illustrated here, after thinning step S40, the wafer 4 (processed wafer 4') has been peeled off from the support member 6 and is adhered to a tape 74 adhered to a frame 72. The processed wafer 4' is peeled off from the support member 6 by such a method as ultrasonication, supply of fluid such as water to the bonding portion 8, or application of an external force, for example.

The frame 72 is an annular, plate-shaped member including such a material as metal and has a hole in the center thereof. The tape 74 having an adhesion layer on one side thereof is adhered to the frame 72 in such a manner as to cover the hole. The tape 74 is a sheet formed in a circular shape, made of resin, and provided on one side thereof with the adhesion layer including such a material as an adhesive. An outer circumferential edge of the tape 74 is adhered to the frame 72. To the central portion of the tape 74, the front side 4a of the wafer 4 (processed wafer 4') is adhered.

In dividing step S50, a laser beam is applied from the irradiation unit 54 to the wafer 4 (processed wafer 4') held by the holding mechanism 56 of the laser processing apparatus 52. The laser beam to be applied has a wavelength that is absorbed by a material of the processed wafer 4'. Here, the wavelength of the laser beam applied to the processed wafer 4' in dividing step S50 may be different from the wavelength of the laser beam applied to the wafer 4 in modifying step S30. In this case, in dividing step S50, an irradiation unit and a laser processing apparatus that are different from those used in modifying step S30 are often used. However, reference characters used in FIG. 8 referred to in the description of modifying step S30 are also used here because mechanisms and the appearance of the apparatuses are common in both cases.

In a state where the laser beam is being applied to the processed wafer 4', the holding mechanism 56 and the irradiation unit 54 are moved relative to each other in a direction along the holding surface 56a, so that ablation processing is performed on the processed wafer 4' along the planned dividing lines 18 (see FIG. 1). In this manner, the processed wafer 4' is divided into chips, and chips are manufactured.

Note that, in dividing step S50, the wafer 4 (processed wafer 4') may be divided along grooves formed along the planned dividing lines 18 in the processed wafer 4' by laser ablation processing or may be divided along modified layers formed along the planned dividing lines 18 in the material of the processed wafer 4' by application of the laser beam.

Alternatively, dividing step S50 may be performed by use of a cutting apparatus. For example, a cutting apparatus similar to the cutting apparatus mentioned in the description of thinning step S40 can be used.

At the time of cutting, the cutting blade cuts into the wafer 4 (processed wafer 4') held by the holding mechanism, while rotating together with the spindle. The cutting unit and the holding mechanism are moved relative to each other in a direction along the holding surface while the cutting blade is cutting into the processed wafer 4', thereby dividing the processed wafer 4' along the planned dividing lines 18 (see FIG. 1). Note that there may be adopted such a method that cutting grooves are formed along the planned dividing lines 18 in the processed wafer 4' by the cutting blade and an external force is thereafter applied, for example, to divide the processed wafer 4' along the cutting grooves.

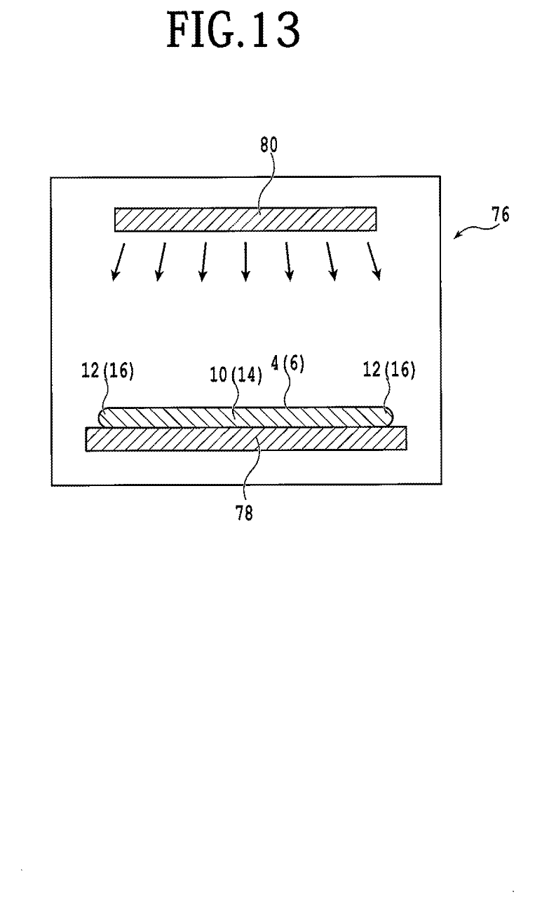

An example of processing in the bonding strength reduction processing step different from the example mentioned above is described. FIGS. 13 to 15 are cross-sectional side views illustrating other examples of processing in the bonding strength reduction processing step. In the processing illustrated in FIGS. 13 to 15, plasma processing apparatuses 76, 82, and 84 that each have a mechanism similar to that of the plasma processing apparatus 46 illustrated in FIG. 6 are respectively used.

The plasma processing apparatus 76 illustrated in FIG. 13 includes, in a chamber, a first electrode 78 and a second electrode 80 provided above the first electrode 78. The first electrode 78 is formed also as a stage that supports the wafer 4 or the support member 6 as a processing target.

The diameter of the second electrode 80 is set to such a dimension that is not excessively large compared to the width (dimension in the direction perpendicular to the thickness direction) of the wafer 4 or the support member 6 as a processing target. Specifically, the dimension of the second electrode 80 is set such that the ratio of the diameter of the second electrode 80 facing the wafer 4 to the width of the wafer 4 (in a case where the wafer 4 is of a disk shape, the width is equal to the diameter) placed on the first electrode 78 is equal to or greater than 0.99 but equal to or smaller than 1.03, more preferably, equal to or greater than 1.00 but equal to or smaller than 1.01, for example.

At the time of plasma processing, the wafer 4 or the support member 6 as a processing target is placed on the first electrode 78 in such a manner that a side to be processed (the side that is to be the bonding portion 8) faces upward (front side, the second electrode 80 side) and the opposite side is in contact with an upper surface of the first electrode 78. In this state, a voltage is applied to a space between the first electrode 78 and the second electrode 80, gas that is present between the first electrode 78 and the second electrode 80 is ionized, and part of plasma thus produced is applied to the wafer 4 or the support member 6 placed on the first electrode 78.

Following the plasma processing, water is supplied to an activated side as appropriate, a hydroxyl group is thus formed, the wafer 4 and the support member 6 are bonded to each other as illustrated in FIG. 1, and the bonded wafer 2 illustrated in FIG. 2 is formed.

Here, in the plasma processing, since the diameter of the second electrode 80 facing the wafer 4 or the support member 6 with the space interposed therebetween is set to the dimension that is not excessively large compared to the width of the wafer 4 or the support member 6 as described above, the density (amount of distribution per space) of plasma applied to the wafer 4 or the support member 6 is smaller in the outer circumferential region 12 or 16 of the wafer 4 or the support member 6 than in the central region 10 or 14. As a result, in the central region 10 or 14, the material constituting the side that is to be the bonding portion 8 of the wafer 4 or the support member 6 as a processing target is activated more strongly than in the outer circumferential region 12 or 16. Accordingly, the bonding strength in the outer circumferential region 12 or 16 is made lower than the bonding strength in the central region 10 or 14.

In the plasma processing apparatus 76 illustrated in FIG. 13, in a case where plasma processing is performed on the wafer 4 having a diameter of 300 mm, for example, if the distance between the first electrode 78 and the second electrode 80 is set to approximately several tens to one hundred millimeters (for example, approximately 50 mm) and an electrode having a diameter of approximately 308 mm is used as the second electrode 80, the entire upper surface of the wafer 4 whose diameter is 300 mm and that faces the second electrode 80 is activated by plasma.

Here, if an electrode having a diameter of approximately 302 mm is used as the second electrode 80, for example, on the upper surface of the wafer 4 whose diameter is 300 mm and that faces the second electrode 80, a region (annular region including an outer circumferential edge and having a width of 3 mm) on an outer side of a circular region including the center and having a diameter of 294 mm is reduced in degree of activation by plasma processing.

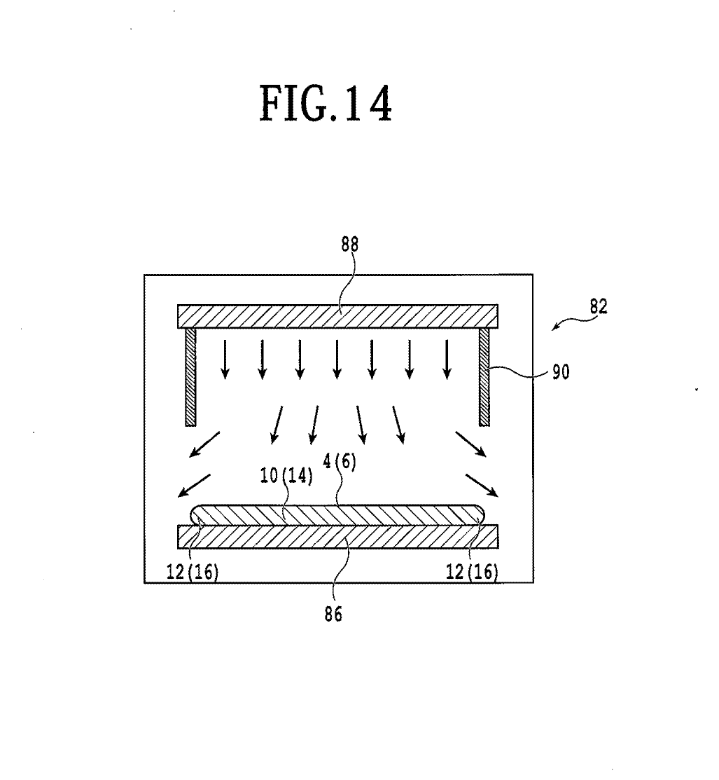

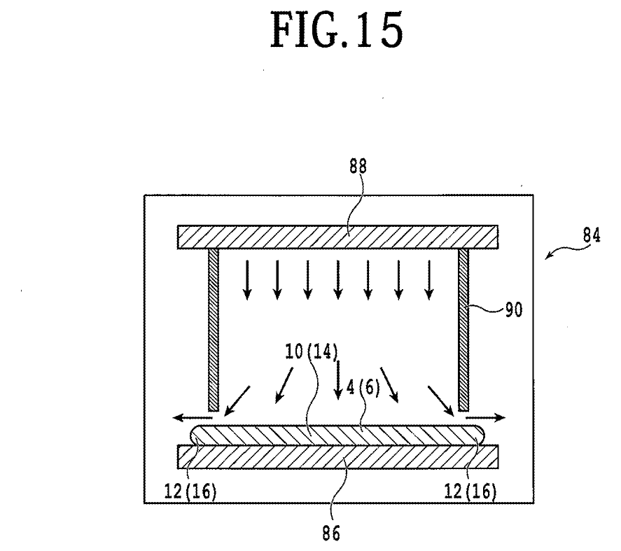

The plasma processing apparatuses 82 and 84 illustrated in FIGS. 14 and 15 each include, in addition to a first electrode 86 and a second electrode 88, a control board 90 in a chamber. The control board 90 is a member having a cylindrical surface shape extending downward (to the first electrode 86 side) from an outer circumferential portion of the second electrode 88. The control board 90 is arranged in such a manner as to surround a space between the first electrode 86 and the second electrode 88 that face each other.

In the plasma processing apparatuses 82 and 84 described above, the degree of strength of plasma processing on the outer circumferential region 12 or 16 of the wafer 4 or the support member 6 as a processing target can be adjusted by setting conditions on the distance between the first electrode 86 and the control board 90 (position of a lower edge of the control board 90) or the inner diameter of the control board 90, for example.

In the plasma processing apparatus 82 illustrated in FIG. 14, the width of an inner circumferential surface (distance between circumferential surfaces facing each other; inner diameter) of the control board 90 having a cylindrical surface shape is set to be the same as or slightly smaller than the width (diameter) of the wafer 4 or the support member 6 placed on the first electrode 86. Specifically, the setting position of the control board 90 on the second electrode 88 is set such that the ratio of the distance (inner diameter) between the inner circumferential surfaces facing each other of the control board 90 to the width (diameter) of the wafer 4 placed on the first electrode 86 is equal to or greater than 0.95 but equal to or smaller than 1.00, more preferably, equal to or greater than 0.97 but equal to or smaller than 0.99, for example.

In a state where the wafer 4 or the support member 6 is placed on the first electrode 86, the position of the control board 90 in plan view (view in a direction perpendicular to electrode surfaces of the first electrode 86 and the second electrode 88) substantially overlaps the outer circumferential edge of the wafer 4 or the support member 6.

Further, the position of an edge (lower edge) of the control board 90 extending from the second electrode 88 is set such that there is a space between the control board 90 and the wafer 4 or the support member 6 in a state where the wafer 4 or the support member 6 is placed on the first electrode 86. The dimension of the control board 90 is set such that the space between the lower edge of the control board 90 and the wafer 4 or the support member 6 (distance in the thickness direction of the wafer 4 or the support member 6) is preferably of equal to or greater than 1 mm but equal to or smaller than 30 mm, more preferably of equal to or greater than 5 mm but equal to or smaller than 15 mm (for example, approximately 10 mm).

At the time of plasma processing, a flow of plasma produced between the first electrode 86 and the second electrode 88 is restricted by the control board 90 and is difficult to escape to the outside of the control board 90. Accordingly, the density of plasma in the space surrounded by the control board 90 is high.

When leaking from the space between the lower edge of the control board 90 and the wafer 4 or the support member 6, plasma is applied to the outer circumferential region 12 or 16 of the wafer 4 or the support member 6. Note that the density of plasma applied to the outer circumferential region 12 or 16 of the wafer 4 or the support member 6 at this time is lower than the density of plasma applied to the central region 10 or 14 of the wafer 4 or the support member 6. As a result, the bonding strength in the outer circumferential region 12 or 16 is made lower than the bonding strength in the central region 10 or 14.

At this time, the bigger the space between the lower edge of the control board 90 and the wafer 4 or the support member 6, the easier it is for plasma to diffuse to the outside of the control board 90. Hence, the difference in the degree of strength of plasma processing between the central region 10 or 14 of the wafer 4 or the support member 6 and the outer circumferential region 12 or 16 of the wafer 4 or the support member 6 is more likely to occur. On the other hand, when the space is too large, the density of plasma is low even in a region closer to the center, and a required bonding strength may not be obtained. Therefore, it is preferable that the size of the space be set in the range described above.

In the plasma processing apparatus 84 illustrated in FIG. 15, the space between the lower edge of the control board 90 and the wafer 4 or the support member 6 is set to be smaller. Specifically, the space is preferably of equal to or greater than 2 mm but equal to or smaller than 10 mm, more preferably of equal to or greater than 3 mm but equal to or smaller than 5 mm (for example, approximately 5 mm). In addition, in the example illustrated here, the width of the inner circumferential surface (distance between the circumferential surfaces facing each other; inner diameter) of the control board 90 having a cylindrical surface shape is set to be even smaller than the inner diameter of the control board 90 illustrated in FIG. 14.

Specifically, in the case of the plasma processing apparatus 84 illustrated in FIG. 15, the setting position of the control board 90 on the second electrode 88 is set such that the ratio of the distance (inner diameter) between the inner circumferential surfaces facing each other of the control board 90 to the width (diameter) of the wafer 4 or the support member 6 placed on the first electrode 86 is equal to or greater than 0.90 but equal to or smaller than 0.98, more preferably, equal to or greater than 0.92 but equal to or smaller than 0.95, for example.

When the width (inner diameter) of a region surrounded by the control board 90 is made small compared to the diameter of the wafer 4 or the support member 6, a region in the wafer 4 or the support member 6 to which plasma having a high density is applied becomes small. To the outer circumferential region 12 or 16, plasma is not applied or is difficult to be applied, so that the outer circumferential region 12 or 16 is less likely to be activated. In this manner, the degree of strength of plasma processing on the outer circumferential region 12 or 16 is adjusted.

Note that, when the wafer 4 and the support member 6 are bonded to each other, the plasma processing described above is performed on at least one of the wafer 4 or the support member 6. In a case where the plasma processing is performed on both the wafer 4 and the support member 6, processing of reducing the bonding strength in the outer circumferential region 12 or 16 (processing of controlling the application amount of plasma to the outer circumferential region 12 or 16) may be performed on both the wafer 4 and the support member 6 or only one of them.

As described above, in the examples illustrated in FIGS. 13 to 15, the bonding strength reduction processing step is performed by making the application amount of plasma per unit area to the outer circumferential region 12 of the side that is to be the bonding portion 8 of the wafer 4 or the outer circumferential region 16 of the side that is to be the bonding portion 8 of the support member 6 smaller than the application amount of plasma per unit area to the central region 10 or 14. In this case, the bonding strength reduction processing step is carried out while the bonding step is being performed.

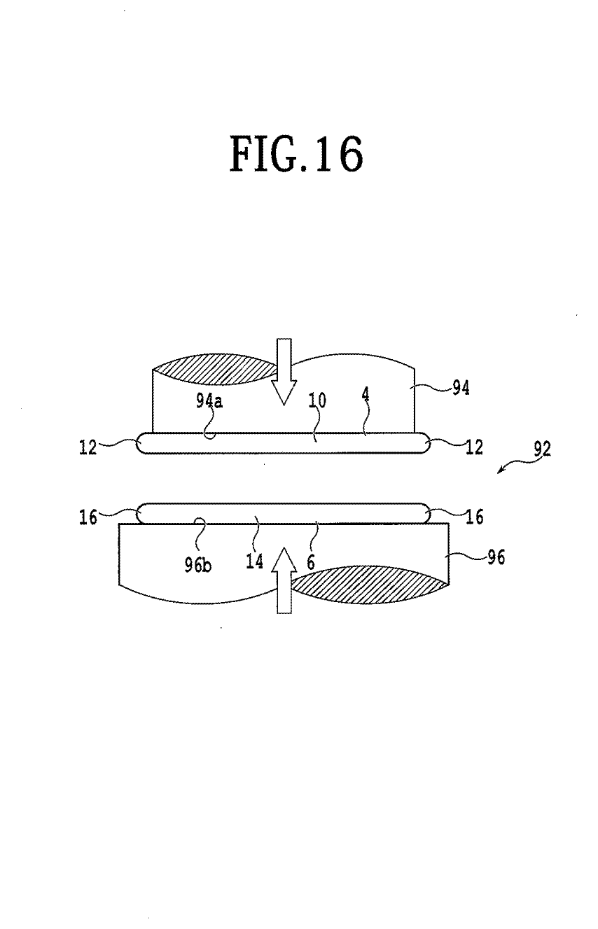

FIG. 16 is a side view illustrating a further example of the bonding strength reduction processing step. In FIG. 16, a bonding apparatus 92 for bonding the wafer 4 and the support member 6 that have been subjected to plasma processing to each other.

The bonding apparatus 92 includes a first pressing unit 94 and a second pressing unit 96. The first pressing unit 94 and the second pressing unit 96 are table-shaped mechanisms including a first holding surface 94a for holding one of the wafer 4 and the support member 6 and a second holding surface 96a for holding the other. For example, by a mechanism using static electricity, the wafer 4 is attracted under suction on one of the first holding surface 94a and the second holding surface 96a while the support member 6 is attracted under suction on the other. Note that, as another mechanism for holding the wafer 4 on one of the first holding surface 94a and the second holding surface 96a and holding the support member 6 on the other, a mechanism that attracts the wafer 4 and the support member 6 under suction by negative pressure may be adopted, for example.

The wafer 4 and the support member 6 are held on the first holding surface 94a of the first pressing unit 94 and the second holding surface 96a of the second pressing unit 96 in such a manner that the sides that are to be the bonding portion 8 (see FIG. 2) face each other. Then, in a state where the sides that are to be the bonding portion 8 are in contact with each other, the wafer 4 and the support member 6 are pressed by the first pressing unit 94 and the second pressing unit 96, so that the wafer 4 and the support member 6 are bonded to each other.

In the example illustrated here, the wafer 4 is held on the first pressing unit 94, the support member 6 is held on the second pressing unit 96, and the width (diameter) of the first holding surface 94a of the first pressing unit 94 is set to be smaller than the width (diameter) of the wafer 4. Accordingly, at least part of the outer circumferential region 12 of the wafer 4 held on the first pressing unit 94 protrudes on the radially outer side from the outer edge of the first holding surface 94a.

Hence, when the wafer 4 and the support member 6 are pressed between the first pressing unit 94 and the second pressing unit 96, pressure applied to the portion of the wafer 4 protruding from the first holding surface 94a and the support member 6 is smaller than pressure applied to the central region 10 of the wafer 4 and the central region 14 of the support member 6. As a result, the regions corresponding to the outer circumferential regions 12 and 16 in the bonding portion 8 have a reduced bonding strength.

Note that, although the diameter of the holding surface of the pressing unit (the first holding surface 94a of the first pressing unit 94) that holds the wafer 4 is set to be smaller than the diameter of the wafer 4 in the example illustrated in FIG. 16, the same effect can be obtained also when, in contrast, the diameter of the holding surface of the pressing unit (the second holding surface 96a of the second pressing unit 96) that holds the support member 6 is set to be smaller than the diameter of the wafer 4. Further, the diameters of both the first holding surface 94a and the second holding surface 96a may be set to be smaller than the diameter of the wafer 4.

As described above, in the method illustrated in FIG. 16, in a state where the side that is to be the bonding portion 8 of the wafer 4 and the side that is to be the bonding portion 8 of the support member 6 are in contact with each other, the wafer 4 and the support member 6 are pressed against each other while pressure applied to the outer circumferential regions 12 and 16 is made smaller than pressure applied to the central regions 10 and 14, and the wafer 4 and the support member 6 are bonded to each other. In this case as well, the bonding strength reduction processing step is carried out while the bonding step is being performed.

With regard to the bonding strength reduction processing step, several kinds of processing are described above as the "processing by which the bonding strength in at least part of the outer circumferential region 12 or 16 is made lower than the bonding strength in the central region 10 or 14." In processing related to formation of one bonded wafer 2, a plurality of kinds of the above-described processing may be used in combination.

Further, the procedure illustrated in FIG. 3 is merely an example. The order of the steps may be changed as appropriate, or another step may be added. For example, modifying step S30 may be performed before bonding step S20.

Other structural and methodological details according to the above-described embodiment can appropriately be modified within a range not deviating from the scope of object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing method of a plate-shaped substrate, the method comprising:
forming a bonded substrate by bonding one side of the plate-shaped substrate and one side of a support member that supports the substrate to each other as a bonding portion;
forming a modified layer inside the substrate by applying a laser beam to the substrate in an annular pattern; and
after the formation of the modified layer, thinning the substrate,
wherein the bonded substrate is formed such that, in the bonding portion, a bonding strength in at least part of an outer circumferential region is lower than a bonding strength in a central region.

2. The substrate processing method according to claim 1,
wherein, before the formation of the bonded substrate or during the formation of the bonded substrate, on at least one of a side that is to be the bonding portion of the substrate or a side that is to be the bonding portion of the support member, bonding strength reduction processing by which, in the bonding portion, the bonding strength in at least part of the outer circumferential region is made lower than the bonding strength in the central region is performed.

3. The substrate processing method according to claim 2,
wherein, in the bonding strength reduction processing, at least part of an outer circumferential region of the side that is to be the bonding portion of the substrate or part of an outer circumferential region of the side that is to be the bonding portion of the support member is polished or ground.

4. The substrate processing method according to claim 2,
wherein, in the bonding strength reduction processing, on at least one of the side that is to be the bonding portion of the substrate or the side that is to be the bonding portion of the support member, an outer circumferential region is made rougher than a central region.

5. The substrate processing method according to claim 2,
wherein, in the formation of the bonded substrate, after plasma is applied to at least one of the side that is to be the bonding portion of the substrate or the side that is to be the bonding portion of the support member, the substrate and the support member are bonded to each other, and
the bonding strength reduction processing is performed by making an application amount of plasma per unit area to an outer circumferential region of the side that is to be the bonding portion of the substrate or an outer circumferential region of the side that is to be the bonding portion of the support member smaller than an application amount of plasma per unit area to a central region.

6. The substrate processing method according to claim 2,
wherein the bonding strength reduction processing is performed by causing the side that is to be the bonding portion of the substrate and the side that is to be the bonding portion of the support member to be in contact with each other and pressing the substrate and the support member against each other while pressure applied to an outer circumferential region is made smaller than pressure applied to a central region, thereby bonding the substrate and the support member to each other.

7. The substrate processing method according to claim 1,
wherein, in the formation of the modified layer, the laser beam is applied in such a manner that a focused spot of the laser beam in the substrate is positioned outward in a radial direction of the substrate as the focused spot approaches the bonding portion in a thickness direction of the substrate.

8. A manufacturing method of a processed substrate in a plate shape, the method comprising:
forming a bonded substrate by bonding one side of the plate-shaped substrate and one side of a support member that supports the substrate to each other as a bonding portion;
forming a modified layer inside the substrate by applying a laser beam to the substrate in an annular pattern; and
after the formation of the modified layer, thinning the substrate,
wherein the bonded substrate is formed such that, in the bonding portion, a bonding strength in at least part of an outer circumferential region is lower than a bonding strength in a central region.

9. The manufacturing method of a processed substrate according to claim 8,
wherein, before the formation of the bonded substrate or during the formation of the bonded substrate, on at least one of a side that is to be the bonding portion of the substrate or a side that is to be the bonding portion of the support member, bonding strength reduction processing by which, in the bonding portion, the bonding strength in at least part of the outer circumferential region is made lower than the bonding strength in the central region is performed.

10. A chip manufacturing method comprising:
forming a bonded substrate by bonding one side of a plate-shaped substrate and one side of a support member that supports the substrate to each other as a bonding portion;
forming a modified layer inside the substrate by applying a laser beam to the substrate in an annular pattern
after the formation of the modified layer, thinning the substrate; and
after the processed substrate is manufactured, dividing the processed substrate,
wherein the bonded substrate is formed such that, in the bonding portion, a bonding strength in at least part of an outer circumferential region is lower than a bonding strength in a central region.

11. The chip manufacturing method according to claim 10,
wherein, before the formation of the bonded substrate or during the formation of the bonded substrate, on at least one of a side that is to be the bonding portion of the substrate or a side that is to be the bonding portion of the support member, bonding strength reduction processing by which, in the bonding portion, the bonding strength in at least part of the outer circumferential region is made lower than the bonding strength in the central region is performed.
